(19) United States
(12) Patent Application Publication
(10) Pub. No.: US 2025/0385671 A1
(43) Pub. Date: Dec. 18, 2025

(54) FLAT-TYPE PROXIMITY SENSOR

(71) Applicant: Keyence Corporation, Osaka (JP)

(72) Inventor: Yasunori KAWAGUCHI, Osaka (JP)

(73) Assignee: Keyence Corporation, Osaka (JP)

(21) Appl. No.: 19/210,090

(22) Filed: May 16, 2025

(30) Foreign Application Priority Data
Jun. 17, 2024 (JP) 2024-097143

(51) Int. Cl. H03K 17/95; H03K 17/945

(52) U.S. Cl. CPC H03K 17/9525; H03K 2017/9455; H03K 2017/9527

(57) ABSTRACT

The flat-type proximity sensor detects a detection object in proximity to a plate-shaped member, and includes a head body, a cable, and an amplifier. The head body includes a case member, a coil, and a head board. The case member has a first surface and a second surface. The coil and the head board are accommodated in the case member, the first surface includes a detection surface, and the second surface is installed on the installation surface. The coil generates a magnetic field by applying a pulse-shaped excitation current. The head board includes a head circuit through which a detection current flows due to a change in a magnetic field. The cable guides the detection current from the head circuit to the amplifier. The amplifier includes a processing circuit that performs processing related to detection of the detection object based on the change in the detection current.

### CROSS-REFERENCE TO RELATED APPLICATIONS

The present application claims foreign priority based on Japanese Patent Application No. 2024-097143, filed Jun. 17, 2024, the contents of which are incorporated herein by reference.

### BACKGROUND OF THE INVENTION

### 1. Technical Field

The invention relates to a flat-type proximity sensor.

### 2. DESCRIPTION OF THE RELATED ART

JP2018-152320A discloses a proximity sensor. The proximity sensor described in JP2018-152320A has a circular shape as is apparent from a shape of reference numeral 5. The circular proximity sensor is also referred to as a cylinder-type proximity sensor or a barrel-type proximity sensor. As illustrated in FIG. 3 of JP2018-152320A, the circular proximity sensor is used by being embedded in nuts and washers of reference numerals 7 to 9.

The proximity sensor has a square shape in addition to the circular shape. The square proximity sensor is also referred to as a flat-type proximity sensor. The proximity sensor is often used by being disposed on a plate-shaped member disposed near a detection object, and the circular proximity sensor disclosed in JP2018-152320A is often used in a state where the plate-shaped member is positioned at a position corresponding to the washer in JP2018-152320A. That is, at least a part of a body portion is often used so as to be positioned on an opposite side of a detection surface with respect to the plate-shaped member, in other words, so as to be embedded in the plate-shaped member. On the other hand, the flat-type proximity sensor is mainly used by being installed on an installation surface which is a front surface of the plate-shaped member or the like.

The flat-type proximity sensor installed on the plate-shaped member or the like detects the detection object passing near the plate-shaped member or the like.

### SUMMARY OF THE INVENTION

Since the flat-type proximity sensor installed on the plate-shaped member or the like protrudes from the plate-shaped member or the like as compared with the circular proximity sensor used to be embedded in the plate-shaped member or the like, there is a risk that the flat-type proximity sensor collides with the detection object passing near the plate-shaped member or the like. In particular, in a case where a path of the detection object is deviated toward the flat-type proximity sensor side, a possibility of collision is further increased. Accordingly, downsizing of the flat-type proximity sensor is desired in order to reduce the possibility of collision with the detection object.

In addition, the flat-type proximity sensor is also required to have a long detection distance. In order to increase the detection distance, it is conceivable to make an excitation current in a pulse shape. However, when the excitation current has the pulse shape, processing for detecting the excitation current is complicated, and thus, a board required for the processing becomes large. Accordingly, in the flat-type proximity sensor in which the excitation current has the pulse shape, when a coil is downsized by the board being large, the detection distance becomes short.

As described above, the flat-type proximity sensor cannot achieve both downsizing and a long detection distance.

The invention has been made in view of the above problems, and an object of the invention is to provide a flat-type proximity sensor capable of achieving both downsizing and a long detection distance.

According to one embodiment of the invention, a flat-type proximity sensor is a flat-type sensor that is installed on an installation surface of a plate-shaped member or the like and detects a detection object in proximity to the plate-shaped member or the like. The flat-type proximity sensor includes a head body installed on the installation surface, a cable, and an amplifier. The head body includes a case member, a coil, and a head board. The case member has a first surface and a second surface. The coil and the head board are accommodated in the case member. The first surface includes a detection surface that detects a detection object in proximity. The second surface is a surface different from the first surface, and is installed on the installation surface. The coil generates a magnetic field by applying a pulse-shaped excitation current. The head board includes a head circuit. A detection current that changes due to a change in a magnetic field flows through the head circuit. The cable guides the detection current from the head circuit to the amplifier. The amplifier includes a processing circuit. The processing circuit performs processing related to detection of the detection object based on the change in the detection current.

According to the flat-type proximity sensor of the invention, both the downsizing and the long detection distance can be achieved.

### BRIEF DESCRIPTION OF THE DRAWINGS

FIG. 1 is a perspective view illustrating an outline of a flat-type proximity sensor according to a first embodiment;

FIG. 2 is an exploded perspective view illustrating an outline of the flat-type proximity sensor;

FIG. 3 is an exploded perspective view of a head body;

FIG. 4 is a sectional view of an electric shield as viewed obliquely from a main plate side;

FIG. 5 is a sectional view of the head body as viewed obliquely from a first surface side;

FIG. 6A is a partially cut sectional view in a case where there is no magnetic shield;

FIG. 6B is a partially cut sectional view in a case where there is a magnetic shield;

FIG. 7 is a sectional view of the head body as viewed obliquely from a second surface side;

FIG. 8 is an exploded perspective view illustrating an outline of a flat-type proximity sensor according to a first modification of the first embodiment;

FIG. 9 is an exploded perspective view illustrating an outline of a flat-type proximity sensor according to a second modification of the first embodiment;

FIG. 10 is an exploded perspective view illustrating an outline of a flat-type proximity sensor according to a second embodiment;

FIG. 11 is a sectional view of a head body as viewed obliquely from a first surface side; and

FIG. 12 is an exploded perspective view illustrating an outline of a flat-type proximity sensor according to a modification of the second embodiment.

### DETAILED DESCRIPTION

Hereinafter, embodiments of the invention will be described with reference to the drawings. Note that, in the drawings, the same or corresponding portions are denoted by the same reference numerals, and the description thereof will not be repeated.

In the following description, terms meaning positions or directions may be used. These terms are used for the sake of convenience to facilitate understanding of the embodiments, and are not related to directions in which actions are actually implemented unless otherwise expressly stated.

### First Embodiment

Hereinafter, a flat-type proximity sensor 100 according to a first embodiment of the invention will be described with reference to the drawings.

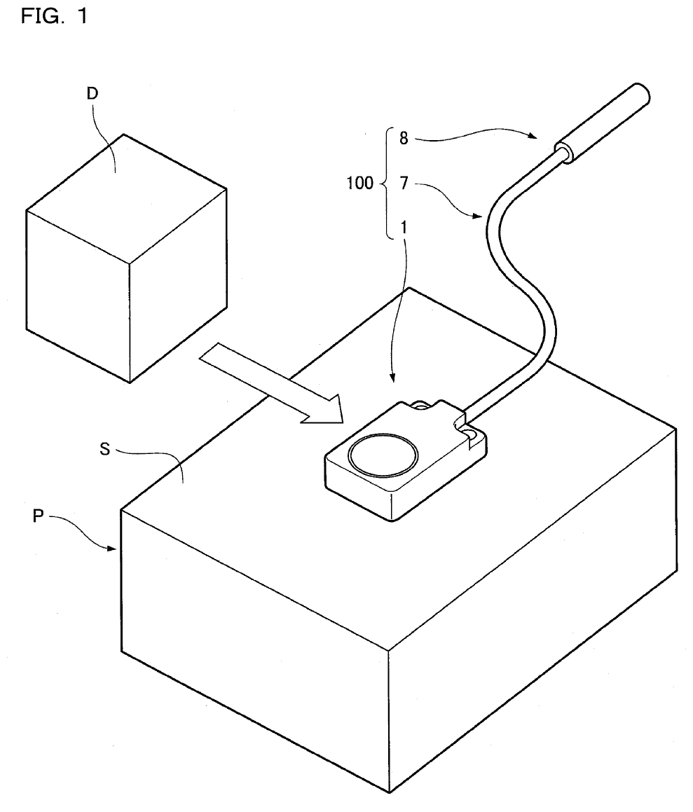

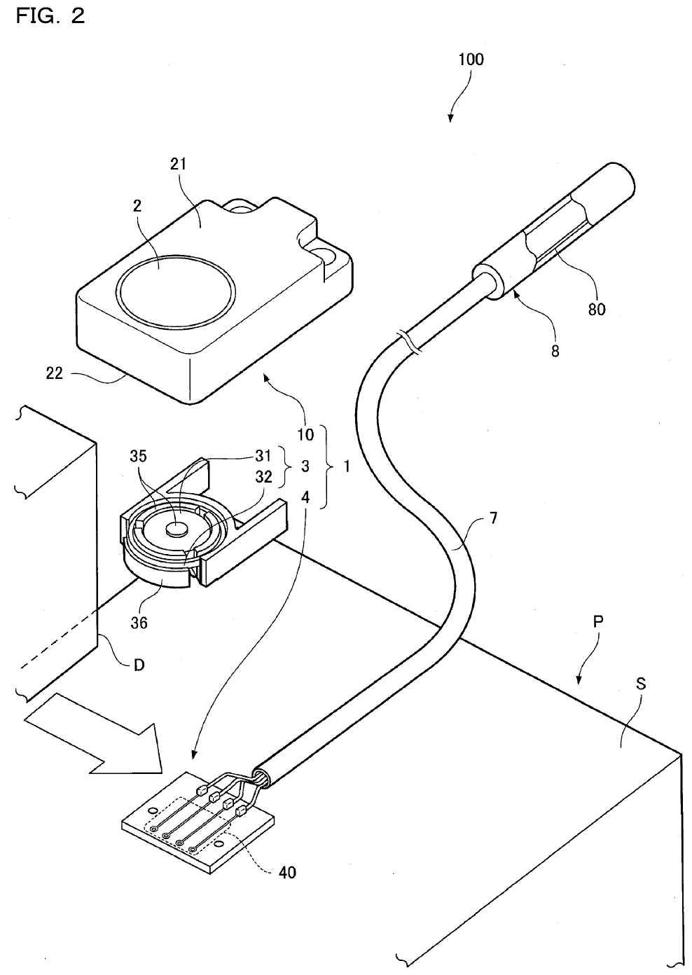

First, an outline of the flat-type proximity sensor 100 will be described with reference to FIGS. 1 and 2. FIG. 1 is a perspective view illustrating the outline of the flat-type proximity sensor 100 according to the first embodiment. FIG. 2 is an exploded perspective view illustrating the outline of the flat-type proximity sensor 100.

As illustrated in FIG. 1, the flat-type proximity sensor 100 is a flat-type sensor that is installed on an installation surface S, which is a front surface of a plate-shaped member P or the like, and detects a detection object D in proximity to the plate-shaped member P or the like or a predetermined position of the plate-shaped member P. The flat-type proximity sensor 100 includes a head body 1 installed on the installation surface S, a cable 7, and an amplifier 8.

As illustrated in FIG. 2, the head body 1 includes a case member 10, a coil 3, and a head board 4. The case member 10 has a first surface 21 and a second surface 22. The coil 3 and the head board 4 are accommodated in the case member 10.

The first surface 21 includes a detection surface 2 that detects the detection object D in proximity. The second surface 22 is a surface different from the first surface 21 and faces a direction opposite to the first surface 21. The second surface comes into contact with the installation surface S when the flat-type proximity sensor 100 is installed on the installation surface S.

The coil 3 generates a magnetic field by applying a pulse-shaped excitation current. The head board 4 includes a head circuit 40. A detection current flowing through the head circuit 40 changes due to a change in the magnetic field.

The cable 7 guides the detection current from the head circuit 40 to the amplifier 8. The amplifier 8 includes a processing circuit 80. The processing circuit 80 performs processing related to the detection of the detection object D based on the change in the detection current.

In general, the flat-type proximity sensor is required to have a long detection distance in order to avoid collision with the detection object D. This is because the head body 1 is often installed on a flat surface such as the installation surface S, and protrudes from the flat surface by a dimension of the head body 1. Proximity sensors using an induced current include a sinusoidal type in which a sinusoidal excitation current is applied to a coil and a pulse type in which a pulse-shaped excitation current is applied to a coil. Both the types detect the change in the current generated in the coil, but a change in the current becomes weaker as a distance between the detection object D and the coil is longer. That is, in order to realize a long detection distance, it is necessary to capture a slight change, but in the sinusoidal type, it is difficult to distinguish between the detection object D and a metal body different from the detection object D. Thus, although the pulse type is used in the present embodiment, the pulse type requires complicated processing such as control of an application timing of the pulse-shaped excitation current to the coil and processing of a current generated in the coil. Accordingly, when the excitation current is formed into a pulse shape in order to realize the long detection distance, a circuit (processing circuit 80) that performs relatively complicated processing such as control of the application timing of the excitation current and calculation based on the change in the detection current is required, and the board on which the processing circuit 80 is mounted becomes large.

When such a large board is accommodated in the head body 1, the head body 1 becomes large, and there is a risk of collision between the head body 1 and the detection object D. Accordingly, in the flat-type proximity sensor 100 described above, the processing circuit 80 is disposed in the amplifier 8 not inside but outside the head body 1, and thus, both downsizing of the head body 1 and the long detection distance can be achieved.

Next, the coil 3 of the flat-type proximity sensor 100 will be described in detail with reference to FIG. 2.

As illustrated in FIG. 2, the coil 3 includes a first coil 31 and a second coil 32. The first coil 31 generates a magnetic field by applying the pulse-shaped excitation current. When the magnetic field is changed by the detection object D, a first detection current flowing through the first coil 31 is changed. The second coil 32 is a coil different from the first coil 31. When the magnetic field is changed by the detection object D, a second detection current flowing through the second coil 32 is changed. The first coil 31 and the second coil 32 are not electrically connected to each other such that the first detection current and the second detection current are processed independently.

The head circuit 40 includes a circuit through which the first detection current flows and a circuit through which the second detection current flows. The first detection current and the second detection current are supplied to the processing circuit 80 independently of each other. The processing circuit 80 performs processing related to the detection of the detection object D based on changes in the first detection current and the second detection current.

In general, the downsizing of the flat-type proximity sensor is desired in order to avoid the collision with the detection object D. In particular, in a case where an object moving along the installation surface S is the detection object D, when a dimension along a normal direction of the detection surface 2 is reduced in the head body 1, the head body hardly collides with the detection object D. In the flat-type proximity sensor, when the head body 1 is downsized, the coil 3 is close to an object disposed around the head body 1 or the plate-shaped member P on which the head body 1 is installed. The flat-type proximity sensor 100 of the present embodiment performs processing related to the detection of the detection object D based on the detection current that changes due to the change in the magnetic field. Since the magnetic field is generated around the coil 3, when a difference between a distance between the coil 3 and the detection object D and a distance between the coil 3 and another metal body is small, a magnetic field change due to the other metal body is reflected in the detection current. Accordingly, when the head body 1 is downsized, the head body 1 is easily influenced by the magnetic field change by a metal object disposed near the head body 1 or the plate-shaped member P in a case where the plate-shaped member P is made of metal.

The flat-type proximity sensor 100 of the present embodiment has two different types of the first coil 31 and the second coil 32. More specifically, the first coil 31 and the second coil 32 are disposed such that the first detection current generated in the first coil 31 and the second detection current generated in the second coil 32 are different in influence and difference between the magnetic field change by the detection object D and the magnetic field change by another peripheral metal body. As a result, it is possible to process a signal from which the influence of the metal body other than the detection object D is excluded based on the first detection current and the second detection current, and it is possible to detect a weak current change. Accordingly, both the downsizing and the long detection distance can be achieved.

The coil 3 of the present embodiment generates a magnetic field by the first coil 31 as transmission, and processes, as different currents, the first detection current flowing through the first coil 31 and the second detection current flowing through the second coil 32 as reception. Accordingly, hereinafter, the flat-type proximity sensor 100 including the first coil 31 and the second coil 32 described above may be referred to as a 1-transmission 2-reception type.

The head body 1 further includes a ferrite core 35 and a core holder 36. The ferrite core 35 guides the magnetic fields generated from the first coil 31 and the second coil 32. The core holder 36 holds the ferrite core 35.

The first coil 31 is disposed such that an axial direction is orthogonal to the detection surface 2. The second coil 32 may be disposed concentrically with the first coil 31. Since a case where the second coil is “disposed concentrically” with the first coil indicates a disposition relationship in which circles are not limited to objects on the same plane, in a case where the second coil 32 is disposed concentrically with respect to the first coil 31, the second coil may be disposed closer to the detection surface 2 side (or an opposite surface side) than the first coil 31.

By the core holder 36, a positional relationship between the first coil 31 and the second coil 32 is stabilized, and the head board 4 can be fixed. Accordingly, since the flat-type proximity sensor 100 suppresses deviation between the coil 3 and the head board 4, further downsizing can be realized.

The second surface 22 installed on the installation surface S is illustrated as an opposite surface to the first surface 21, but may be a surface other than the opposite surface as long as the surface is different from the first surface 21. The head circuit 40 does not need to perform any processing on the detection current, and for example, may simply guide the detection current from the coil 3 to the cable 7 (role as an electric wire). A coil wire of the coil 3 and the cable 7 are connected via the head circuit 40 provided on the head board 4, and thus, assemblability is improved.

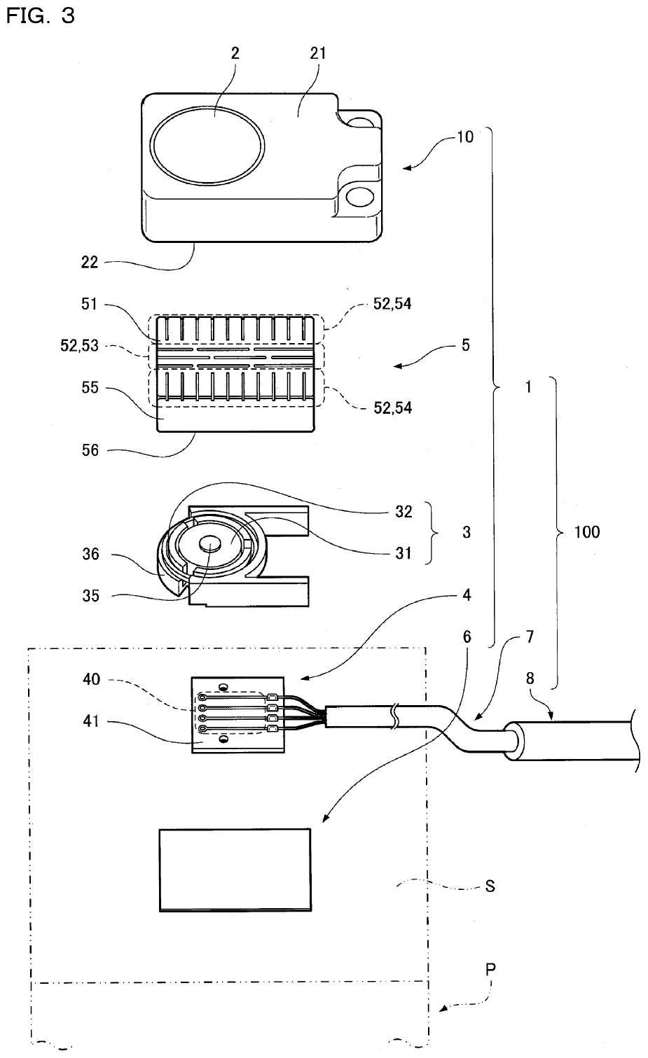

Next, a configuration for reducing external noise generated in the flat-type proximity sensor 100 will be described with reference to FIG. 3. FIG. 3 is an exploded perspective view of the head body 1.

As illustrated in FIG. 3, the flat-type proximity sensor 100 further includes an electric shield 5. The electric shield 5 includes a main plate 51 along the detection surface 2 and side plates 55 erected on an outer peripheral edge of the main plate 51. A cut 52 is formed in the main plate 51.

The electric shield 5 is made of a conductive member in order to absorb external noise. However, when the conductive member covers the coil 3, an eddy current is generated on the electric shield 5 due to the magnetic field change, and there is a possibility that the detection is influenced by the eddy current. In particular, in the present embodiment, the eddy current is easily generated in the main plate 51 positioned between the coil 3 and the detection surface 2. The cut 52 formed in the main plate 51 of the electric shield 5 suppresses a loop of the eddy current generated in the main plate 51. The loop of the eddy current is suppressed, and thus, the influence of the external noise on the detection is reduced while the influence of the eddy current on the detection is suppressed. Accordingly, the flat-type proximity sensor 100 can realize a longer detection distance. Note that, the electric shield 5 is grounded via a wiring (not illustrated) included in the cable 7.

The cut 52 formed in the main plate 51 has a plurality of vertical cuts 53 along a longitudinal direction of the main plate 51 and a plurality of lateral cuts 54 along a lateral direction of the main plate 51. For example, the plurality of vertical cuts 53 are formed in series and in three rows at a center in the lateral direction of the main plate 51. For example, the plurality of lateral cuts 54 are formed in parallel and in two rows at positions sandwiching the plurality of vertical cuts 53.

The side plate 55 erected on the main plate 51 is not necessarily perpendicular to the main plate 51, and may be an acute angle or an obtuse angle with respect to the main plate 51. In order to achieve further downsizing, an angle of the side plate 55 with respect to the main plate 51 is set such that a shape of the electric shield 5 is along an inner surface of the case member 10.

The main plate 51 and the side plates 55 are preferably along the inner surface of the case member 10. The main plate 51 and the side plates 55 constituting the electric shield 5 are along the inner surface of the case member 10, and thus, an unnecessary space is reduced inside the case member 10. Accordingly, the flat-type proximity sensor 100 can be further downsized.

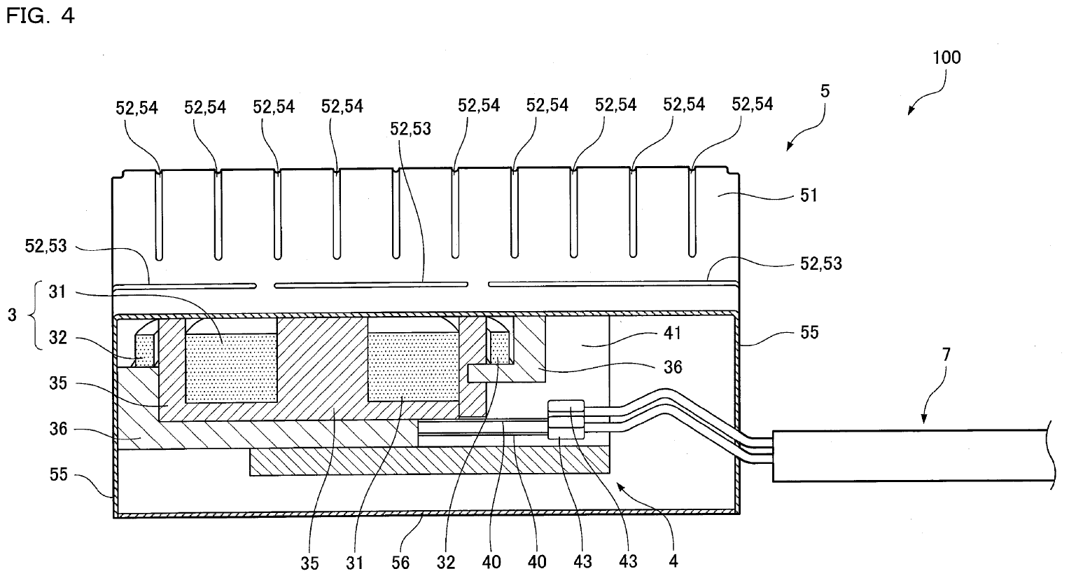

Next, details of the electric shield 5 will be described with reference to FIG. 4. FIG. 4 is a sectional view of the electric shield 5 as viewed obliquely from the main plate 51 side.

As illustrated in FIG. 4, the electric shield 5 further includes a back plate 56. The back plate 56 faces the main plate 51 and is connected to the side plates 55. The main plate 51, the side plates 55, and the back plate 56 surround the head board 4. The electric shield 5 surrounds the head board 4, and thus, the influence of the external noise on the head board 4 can be reduced. As a method for reducing the influence of the noise, a method using an amplifier circuit that amplifies a signal such that the influence of the noise becomes relatively small is known. However, the influence of the noise on the coil 3 and a wiring connected to the coil 3 can be reduced by the configuration of the electric shield 5 even though a separate amplifier circuit is not provided. Accordingly, the flat-type proximity sensor 100 can further downsize the head body I as compared with a configuration in which a board on which the amplifier circuit is provided is disposed in the head body 1 or a configuration in which the head body 1 includes the head board 4 in which the amplifier circuit is provided.

The electric shield 5 surrounds not only the head board 4 but also the coil 3, the ferrite core 35, and the core holder 36. The head board 4, the coil 3, the ferrite core 35, and the core holder 36 are assembled to the electric shield 5 inside the electric shield 5.

The main plate 51 and the back plate 56 each have a rectangular shape. Four side plates 55 are connected to both long sides and both short sides of the main plate 51. The back plate 56 is connected to one (for example, the side plate 55 connected to the long side of the main plate 51) of the four side plates 55.

The electric shield 5 is a sheet metal structure. That is, the electric shield 5 is formed in a box shape by bending from one metal plate in which the plurality of vertical cuts 53 and the plurality of lateral cuts 54 are formed. Specifically, four side plates 55 are bent from one metal plate so as to be erected with respect to the main plate 51, and further, the back plate 56 is bent so as to be erected with respect to one side plate 55. Such bending forms the box-shaped electric shield 5 that can be erected on its own. When the inner surface of the case member 10 also has a box shape, the electric shield 5 has a box shape, and thus, the electric shield extends along the inner surface of the case member 10. In the present embodiment, the electric shield 5 has a sheet metal structure, but may be made of a conductive member capable of absorbing the external noise, and may be made of, for example, a flexible board. In addition, in the present embodiment, the head board 4 and the electric shield 5 are made of different members, but for example, may be made of one flexible board, and a board portion where a circuit is provided may be surrounded by another portion. Note that, when the electric shield 5 is made of a flexible board, the cut provided in the main plate 51 may be realized not by a cut in the flexible board but by a cut in a conductive portion (for example, copper foil) provided in the flexible board.

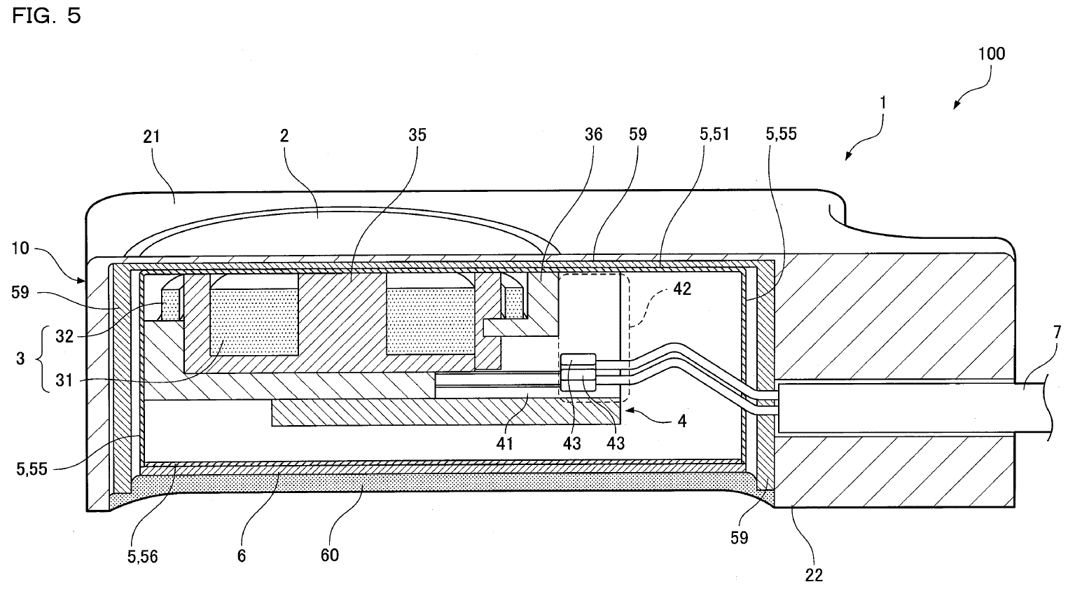

Next, insulation in the flat-type proximity sensor 100 will be described with reference to FIG. 5. FIG. 5 is a sectional view of the head body 1 as viewed obliquely from the first surface 21 side.

The case member 10 is made of metal. The head body 1 further includes an insulating member 59. The insulating member 59 insulates the case member 10 and the electric shield 5 from each other.

Since the case member 10 is made of metal, the strength of the case member 10 having a risk of colliding with the detection object D is increased. Accordingly, the flat-type proximity sensor 100 can reduce failure of the case member 10. Further, the flat-type proximity sensor 100 can reduce a risk of electric leakage from the case member 10 by insulating the metal case member 10 and the electric shield 5 from each other.

The insulating member 59 includes an insulating resin (insulator). The insulating member 59 includes the insulating resin, and thus, the case member 10 and the electric shield 5 are sufficiently insulated from each other. Accordingly, the risk of the electric leakage from the case member 10 can be reduced.

The insulating member 59 is an insulating material coated on the inner surface of the case member 10. The insulating member 59 is in a state of being coated on the inner surface of the case member 10, and thus, an unnecessary space is reduced inside the case member 10. Accordingly, the flat-type proximity sensor 100 can be further downsized. In particular, in a case where the case member 10 has a box shape and a widest surface (for example, an opposite surface) of the case member 10 is exposed, it is easy to coat the inner surface of the case member 10 with the insulating material.

The coating of the insulating material is, for example, coating by vapor deposition such as parylene coating, coating by painting such as resin painting, or coating by sintering such as inorganic sintered coating.

The detection surface 2 is made of metal. The detection surface 2 is made of metal, and thus, the strength of the detection surface 2 having a risk of colliding with the detection object D is increased. Accordingly, the flat-type proximity sensor 100 can reduce the failure of the detection surface 2.

The flat-type proximity sensor 100 further includes a magnetic shield 6. The magnetic shield 6 is disposed on an opposite surface to the detection surface 2. Accordingly, when the head body 1 is installed on the installation surface S, the magnetic shield 6 is positioned between the coil 3 and the plate-shaped member P having the installation surface S. The magnetic shield 6 is disposed on the opposite surface to the detection surface 2 with respect to the coil 3, the magnetic shield 6 is disposed at a position relatively close to the plate-shaped member P. As described above, the change in the magnetic field by the plate-shaped member P influences the detection current. This influence is particularly large in a case where the plate-shaped member P is made of metal. In a case where the change in the current caused by the magnetic field change by the detection object D is weak, that is, in a case where the detection object D relatively separated from the coil 3 is detected, the presence of the plate-shaped member P influences the detection result. Although details will be described later, the influence on the detection current from the plate-shaped member P is reduced by disposing the magnetic shield 6 near the plate-shaped member P. Accordingly, the flat-type proximity sensor 100 can realize a longer detection distance.

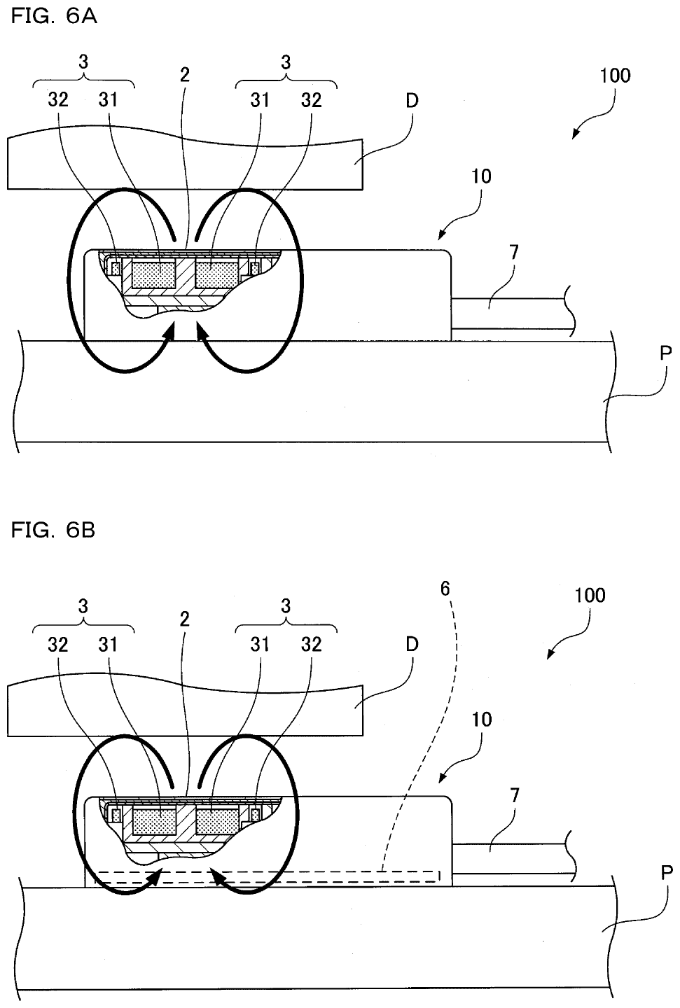

Hereinafter, a function of the magnetic shield 6 will be described with reference to FIGS. 6A and 6B. FIG. 6A is a partially cut sectional view in a case where there is no magnetic shield 6. FIG. 6B is a partially cut sectional view in a case where there is the magnetic shield 6.

As illustrated in FIG. 6A, in a case where there is no magnetic shield 6, a magnetic field (illustrated by a thick arrow) from the coil 3 comes out of the detection surface 2, and then bypasses and returns from the opposite surface to the coil 3. The magnetic field that is largely bypassed easily changes due to the plate-shaped member P by deeply passing through the plate-shaped member P close to the opposite surface. In particular, in a case where the plate-shaped member P or the like is made of metal, the influence on the magnetic field is large.

On the other hand, as illustrated in FIG. 6B, in a case where there is the magnetic shield 6, a magnetic field (illustrated by a thick arrow) bypasses and approaches the magnetic shield 6 when returning from the opposite surface to the coil 3. That is, the amount of magnetic flux lines passing through the plate-shaped member P among magnetic flux lines constituting the magnetic field from the coil 3 is reduced, and the magnetic flux lines passing through the plate-shaped member P also pass shallowly. Thus, the influence of the plate-shaped member P on the magnetic field from the coil 3 is reduced, and thus, the influence of the plate-shaped member P on the detection result is reduced.

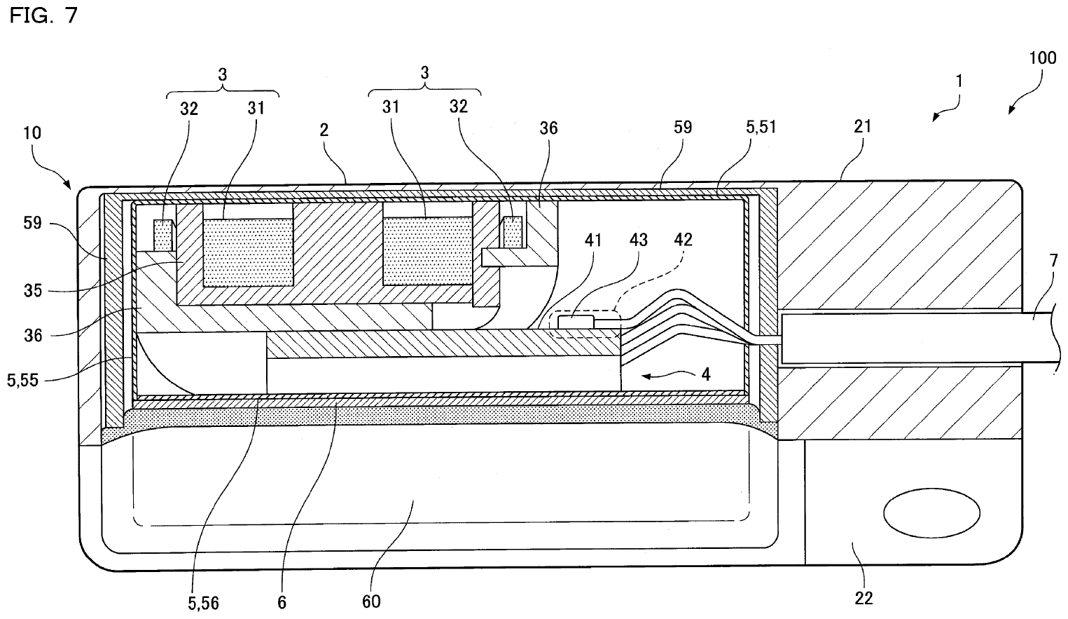

Next, the opposite surface to the detection surface 2 will be described in detail with reference to FIG. 7. FIG. 7 is a sectional view of the head body 1 as viewed obliquely from the second surface 22 side.

The case member 10 exposes the opposite surface to the first surface 21. The head body 1 further includes a filling resin 60 on the exposed opposite surface of the case member 10. The filling resin 60 protects the inside of the case member 10 and reduces the influence on the magnetic field. As compared with a case where the entire opposite surface is covered with a metal member, since the amount of members that can influence a detection result is reduced, the flat-type proximity sensor 100 can realize a longer detection distance.

A front surface of the filling resin 60 is not limited to a flat surface, and may be a curved surface or a surface having irregularities. As illustrated in FIG. 7, the front surface of the filling resin 60 is, for example, a surface in which a central portion is recessed into the case member 10 rather than a peripheral edge portion. In a case where such a front surface of the filling resin 60 is the second surface 22, the second surface 22 comes into contact with the installation surface S only at the peripheral edge portion of the filling resin 60 instead of the entire surface. In a case where the front surface of the filling resin 60 is the second surface 22, it is preferable that the front surface of the filling resin 60 does not protrude from the case member 10 (is a flat surface or a recessed surface) in order to prevent the case member 10 from being too close to a path of the detection object D.

The head board 4 includes a board front surface 41 facing a back surface of the first surface 21 and terminals 43 provided on the board front surface 41. The board front surface 41 has a non-shielding portion 42 that is not shielded inside the case member 10. The terminals 43 are positioned in the non-shielding portion 42.

The terminals 43 are positioned in the non-shielding portion 42, and thus, it is easy to provide the terminals 43 on the board front surface 41 by soldering or the like. Accordingly, the flat-type proximity sensor 100 can be easily manufactured.

The non-shielding portion 42 where the board front surface 41 is not shielded inside the case member 10 is a portion that is not projected by configuration members 3, 35, and 36 when the configuration members (coil 3, ferrite core 35, and core holder 36) excluding the electric shield 5 are projected perpendicularly to the board front surface 41 inside the case member 10.

### First Modification of First Embodiment

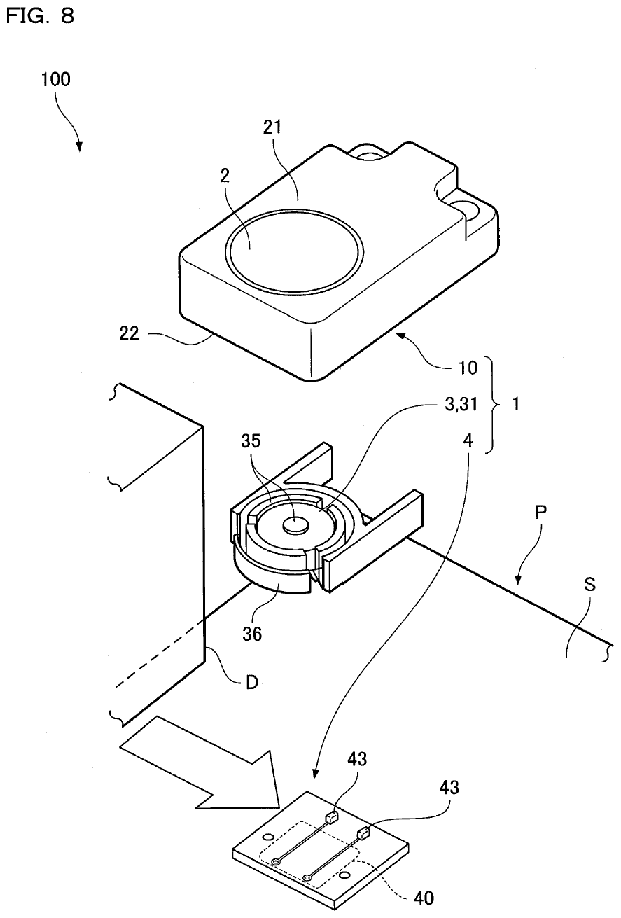

Hereinafter, a first modification of the flat-type proximity sensor 100 according to the first embodiment will be described with reference to FIG. 8. FIG. 8 is an exploded perspective view illustrating an outline of a flat-type proximity sensor 100 according to the first modification of the first embodiment.

As compared with the first embodiment, the flat-type proximity sensor 100 of the first modification may not include an amplifier 8 and a cable 7 connecting the amplifier 8 and a head body 1, and the excitation current is not limited to the pulse shape.

First, a premise of the first modification will be described. In a case where the proximity sensor described in JP2018-152320A as a background art is the flat-type, there is a problem that detection accuracy is not sufficient.

Therefore, an object of the technical idea according to the flat-type proximity sensor 100 of the first modification is to improve detection accuracy.

As illustrated in FIG. 8, the flat-type proximity sensor 100 is a flat-type sensor that is installed on an installation surface S of a plate-shaped member P or the like and detects a detection object D in proximity to the plate-shaped member P or the like. The flat-type proximity sensor 100 includes the head body 1 installed on the installation surface S.

The head body 1 includes a case member 10, a first coil 31 (an example of a coil 3), and a head board 4. The case member 10 has a first surface 21 and a second surface 22. The first coil 31 and the head board 4 are accommodated in the case member 10.

The first surface 21 includes a detection surface 2 that detects the detection object D in proximity. The second surface 22 is a surface different from the first surface 21 and is installed on the installation surface S.

The first coil 31 generates a magnetic field by applying an excitation current. The head board 4 includes a head circuit 40. A first detection current (an example of a detection current) flowing through the head circuit 40 changes due to a change in the magnetic field.

In the flat-type proximity sensor 100 of the first modification, the head body 1 includes the case member 10, the coil 3, and the head board 4, and thus, the detection accuracy can be improved.

The excitation current applied to the first coil 31 may have a shape other than a pulse shape (for example, sinusoidal or the like), or may have a pulse shape. The flat-type proximity sensor 100 of the first modification may include the cable 7 and the amplifier 8 illustrated in FIG. 1.

### Second Modification of First Embodiment

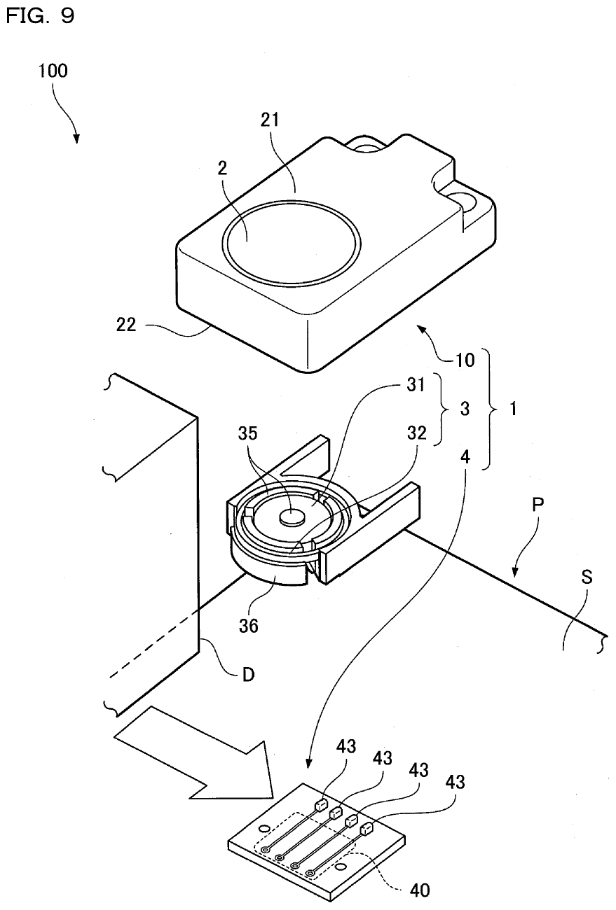

Next, a second modification of the flat-type proximity sensor 100 according to the first embodiment will be described with reference to FIG. 9. FIG. 9 is an exploded perspective view illustrating an outline of a flat-type proximity sensor 100 according to the second modification of the first embodiment.

In the flat-type proximity sensor 100 of the second modification, as compared with the first modification, a coil 3 also includes a second coil 32, and a first detection current generated in the first coil 31 and a second detection current generated in the second coil 32 are processed independently of each other in the 1-transmission 2-reception type.

First, a premise of the second modification will be described. The flat-type proximity sensor 100 in which the proximity sensor described in JP2018-152320A as the background art is the flat-type is used by being installed on the installation surface S of the plate-shaped member P or the like.

Since the flat-type proximity sensor 100 installed on the plate-shaped member P or the like protrudes from the plate-shaped member P or the like, there is a risk of colliding with the detection object D passing near the plate-shaped member P or the like. In particular, when the path of the detection object D is deviated toward the flat-type proximity sensor 100 side, the possibility of collision is further increased. Accordingly, the downsizing of the flat-type proximity sensor 100 is desired in order to reduce a possibility of collision with the detection object D.

In the flat-type proximity sensor 100, when the head body 1 is downsized, the coil 3, which is a main device for detection, and the case member 10 accommodating the coil 3 become close to each other. As a result, a magnetic field from the coil 3 is easily influenced by the plate-shaped member P or the like (particularly, in the case of being made of metal) outside the case member 10. When the magnetic field is influenced by the plate-shaped member P or the like (particularly, in the case of being made of metal), a detection distance becomes short.

Therefore, an object of the technical idea according to the flat-type proximity sensor 100 of the second modification is to achieve both downsizing and a long detection distance.

As illustrated in FIG. 9, the flat-type proximity sensor 100 is a flat-type sensor that is installed on the installation surface S of the plate-shaped member P or the like and detects the detection object D in proximity to the plate-shaped member P or the like. The flat-type proximity sensor 100 includes the head body 1 installed on the installation surface S.

The head body 1 includes a case member 10, a coil 3, and a head board 4. The case member 10 has a first surface 21 and a second surface 22. The coil 3 and the head board 4 are accommodated in the case member 10.

The first surface 21 includes a detection surface 2 that detects the detection object D in proximity. The second surface 22 is a surface different from the first surface 21 and is installed on the installation surface S.

The coil 3 includes a first coil 31 and a second coil 32. The first coil 31 generates a magnetic field by applying an excitation current. The second coil 32 is different from the first coil 31. A first detection current flows through the first coil 31, a second detection current flows through the second coil 32, and the first detection current and the second detection current change due to a change in the magnetic field.

The head board 4 includes a head circuit 40. The first detection current and the second detection current flow through the head circuit 40.

Accordingly, the flat-type proximity sensor 100 described above has two different types of the first coil 31 and the second coil 32. More specifically, the first coil 31 and the second coil 32 are disposed such that the first detection current generated in the first coil 31 and the second detection current generated in the second coil 32 are different in influence and difference between the magnetic field change by the detection object D and the magnetic field change by another peripheral metal body. As a result, it is possible to process a signal from which the influence other than the detection object D is excluded based on the first detection current and the second detection current, and it is possible to detect a weak current change. Accordingly, both the downsizing and the long detection distance can be achieved.

The excitation current applied to the first coil 31 may have a shape other than a pulse shape (for example, sinusoidal or the like), or may have a pulse shape.

The flat-type proximity sensor 100 of the second modification may include the cable 7 and the amplifier 8 illustrated in FIG. 1.

### Second Embodiment

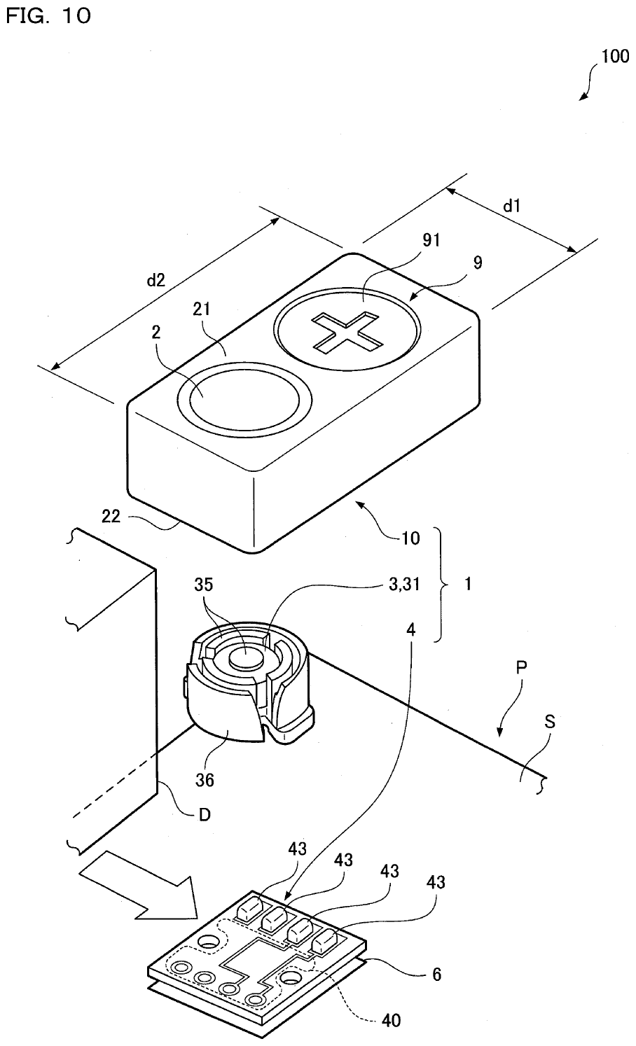

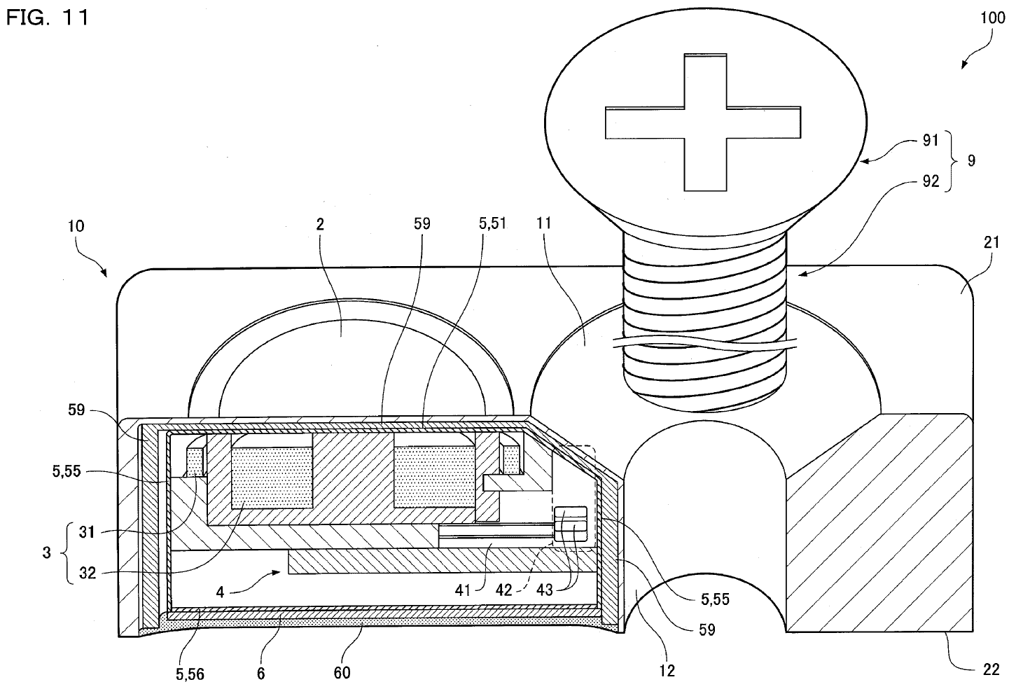

Hereinafter, a flat-type proximity sensor 100 according to a second embodiment will be described with reference to FIGS. 10 and 11. FIG. 10 is an exploded perspective view illustrating an outline of the flat-type proximity sensor 100 according to the second embodiment. FIG. 11 is a sectional view of a head body 1 as viewed obliquely from a first surface 21 side.

The flat-type proximity sensor 100 according to the second embodiment is further downsized as compared with the first embodiment.

First, a premise of the second embodiment will be described. The flat-type proximity sensor 100 in which the proximity sensor described in JP2018-152320A as the background art is the flat-type is used by being installed on the installation surface S of the plate-shaped member P or the like.

Since the flat-type proximity sensor 100 installed on the plate-shaped member P or the like protrudes from the plate-shaped member P or the like, there is a risk of colliding with the detection object D passing near the plate-shaped member P or the like. In particular, when the path of the detection object D is deviated toward the flat-type proximity sensor 100 side, the possibility of collision is further increased.

In the flat-type proximity sensor 100 in which the head body 1 is downsized, the detection distance may be equal to or less than the deviation of the detection object D. In this case, there is a risk that the detection surface 2 of the head body 1 that detects the detection object D collides with the detection object D and fails due to damage.

Therefore, an object of the technical idea according to the flat-type proximity sensor 100 of the second embodiment is to reduce the failure of the detection surface 2 even though the flat-type proximity sensor is downsized.

As illustrated in FIG. 10, the flat-type proximity sensor 100 is a flat-type sensor that is installed on the installation surface S of the plate-shaped member P or the like and detects the detection object D in proximity to the plate-shaped member P or the like. The flat-type proximity sensor 100 includes the head body 1 installed on the installation surface S.

The head body 1 includes a case member 10, a first coil 31 (an example of a coil 3), and a head board 4. The case member 10 has a first surface 21 and a second surface 22. The first coil 31 and the head board 4 are accommodated in the case member 10.

The first surface 21 includes the detection surface 2 made of metal for detecting the detection object D in proximity. The first surface 21 has a substantially rectangular shape, and has a diameter dimension d1 in a direction along a short side and a diameter dimension d2 in a direction along a long side. That is, a minimum diameter dimension of the diameter dimension of the first surface 21 is d1, and the diameter dimension d1 is 18 mm or less. The second surface 22 is a surface different from the first surface 21 and is installed on the installation surface S.

The first coil 31 generates a magnetic field by applying an excitation current. The head board 4 includes a head circuit 40. A first detection current (an example of a detection current) flowing through the head circuit 40 changes due to a change in the magnetic field.

The first coil 31 is accommodated in the case member 10 such that an axial direction is orthogonal to the first surface 21 including the detection surface 2. Thus, an outer diameter of the first coil 31 is smaller than the minimum diameter dimension d1 of the first surface 21 of the case member 10. That is, when the minimum diameter dimension d1 of the first surface 21 is as small as 18 mm or less, the first coil 31 further becomes smaller.

Since the detection surface 2 of the head body 1 is disposed close to the path of the detection object D in order to sufficiently detect even the small first coil 31, there is a risk of colliding with the detection object D. Here, the detection surface 2 is made of metal, and thus, the strength of the detection surface 2 having a risk of colliding with the detection object D is increased. Accordingly, the flat-type proximity sensor 100 can reduce the failure of the detection surface 2.

In the present second embodiment, the detection surface 2 and a through-hole into which an attachment screw 9 is inserted are provided side by side in a direction orthogonal to the minimum diameter dimension d1. Further, in the present second embodiment, the minimum diameter dimension d1 is approximately 8 mm, and an outer diameter of the coil 3 is also approximately 8 mm. The outer diameter of the coil 3 herein refers to an outer diameter of a coil portion around which a coil wire is wound or a ferrite core. As described above, in a case where the minimum diameter dimension d1 of the case member 10 is smaller than twice the outer diameter of the coil 3, at least a part of the coil 3 is positioned at a center of the minimum diameter dimension d1 in a diameter direction. It is preferable that the through-hole into which the attachment screw 9 is inserted is disposed near a center of the diameter dimension d1 in the diameter direction from the viewpoint of convenience of an attachment work. Accordingly, it is difficult to take a sufficient distance between the coil 3 and the attachment screw 9 in the diameter direction of the diameter dimension d1. In addition, when the coil 3 and the through-hole into which the attachment screw 9 is inserted are separated from each other in a diameter direction of a diameter dimension d2, since the head body 1 is increased in size in the diameter direction and the detection surface 2 is easily deviated by a relatively large angle deviation near the attachment screw 9, the convenience of the attachment work deteriorates. Accordingly, it is difficult to separate the coil 3 and the through-hole into which the attachment screw 9 is inserted in the diameter direction of the diameter dimension d2, and the coil 3 and the attachment screw 9 have to approach each other. That is, in a case where the minimum diameter dimension d1 is smaller than twice the outer diameter of the coil 3, since a difference hardly occurs between the distance between the coil 3 and the detection object D and the distance between the coil 3 and the attachment screw 9 which is the metal body, when the detection distance is increased, there is a risk that the accuracy of the detection result is lowered due to the influence of the magnetic field by the attachment screw 9.

As described above, in the configuration in which the attachment screw 9 is disposed near the coil 3, in order to improve the accuracy of the detection result, it is necessary to limit a region where the magnetic field is generated by the coil 3 to a certain range, in other words, to limit the detection distance. Even with such a configuration, since the detection surface 2 of the head body 1 is disposed close to the path of the detection object D such that the detection object D can be sufficiently detected, the possibility of collision between the detection object D and the detection surface 2 increases. Since the detection surface 2 is made of metal, a risk that the detection surface 2 is damaged in a case where the detection object D collides with the detection surface 2 is reduced.

Further, in the present embodiment, a center of the coil 3 is positioned in a range where the through-hole into which the attachment screw 9 is inserted is present in the diameter direction of the minimum diameter dimension d1. In other words, a straight line passing through the center of the coil 3 and extending in a direction intersecting the diameter direction is in a positional relationship of passing through the through-hole into which the attachment screw 9 is inserted. In such a positional relationship, when the detection surface 2 and the through-hole into which the attachment screw 9 is inserted are tried to be separated from each other, as described above, there is a risk that the size of the diameter dimension d2 in the diameter direction increases or the convenience of attachment decreases, and the detection surface 2 and the through-hole into which the attachment screw 9 is inserted are provided in a relatively close positional relationship. Thus, as described above, it is necessary to limit the detection distance in order to solve the decrease in accuracy of the detection result due to the influence of the magnetic field by the attachment screw 9. As described above, when the detection distance is limited, since the head body 1 is disposed closer to the path of the detection object D, the possibility of collision between the detection object D and the detection surface 2 increases. That is, even in the configuration in which the center of the coil 3 is positioned in the range where the through-hole into which the attachment screw 9 is inserted is present in the diameter direction of the minimum diameter dimension d1, the detection surface 2 is made of metal, and thus, the risk that the detection surface 2 is damaged in a case where the detection object D collides with the detection surface 2 is reduced.

As illustrated in FIG. 11, in the flat-type proximity sensor 100 according to the second embodiment, the 1-transmission 2-reception type described in the first embodiment, that is, the coil 3 may have the first coil 31 and the second coil 32. As a result, the flat-type proximity sensor 100 according to the second embodiment also exhibits the effects of the 1-transmission 2-reception type described in the first embodiment.

The flat-type proximity sensor 100 according to the second embodiment may further include the electric shield 5 described in the first embodiment. In addition, the electric shield 5 may have the sheet metal structure and the box shape described in the first embodiment. Further, the electric shield 5 may surround the head board 4 as described in the first embodiment. As a result, the flat-type proximity sensor 100 according to the second embodiment also has the effect of the electric shield 5 described in the first embodiment. Note that, as described in the first embodiment, the electric shield 5 may be made of a flexible board.

In the flat-type proximity sensor 100 according to the second embodiment, as described in the first embodiment, the electric shield 5 may have a shape along the inner surface of the case member 10. Since the shape of the case member 10 is different between the first embodiment and the second embodiment, the shape of the electric shield 5 is also different between the first embodiment and the second embodiment.

Specifically, in the second embodiment, since the head body 1 is smaller than that in the first embodiment, the attachment screw 9 is relatively larger than the case member 10. Accordingly, the shape of the case member 10 is partially influenced by the shape of the attachment screw 9.

In the shape of the case member 10, a portion influenced by the shape of the attachment screw 9 is a surface layer portion 11 along a head portion 91 of the attachment screw 9 and a deep layer portion 12 along a shaft portion 92 of the attachment screw 9. Accordingly, in a case where the attachment screw 9 is a flat-head screw, the surface layer portion 11 is a part of a truncated cone shape (a shape of the head portion 91 of the flat-head screw), and deep layer portion 12 is a part of a cylindrical shape (a shape of shaft portion 92 of the flat-head screw).

The electric shield 5 of the second embodiment is along the surface layer portion 11 and the deep layer portion 12, and also along a portion which is not influenced by the shape of the attachment screw 9 on the inner surface of the case member 10. The electric shield 5 is along the inner surface of the case member 10, and thus, an unnecessary space is reduced inside the case member 10. Accordingly, the flat-type proximity sensor 100 can be further downsized.

Considering that the minimum diameter dimension d1 of the diameter dimensions d1 and d2 of the first surface 21 is 18 mm or less, the attachment screw 9 is preferably a M3 flat-head screw (one) in the JIS standard. Since the attachment screw 9 is the M3 flat-head screw, the inside of the case member 10 is not narrowed more than necessary while the installation on the installation surface S by the attachment screw 9 is sufficiently secured.

The flat-type proximity sensor 100 according to the second embodiment may further include the insulating member 59 described in the first embodiment. In addition, the insulating member 59 may be the insulating resin (insulator) described in the first embodiment. Further, as described in the first embodiment, the insulating member 59 may be an insulating material coated on the inner surface of the case member 10. As a result, the flat-type proximity sensor 100 according to the second embodiment also has the effect of the insulating member 59 described in the first embodiment.

The flat-type proximity sensor 100 according to the second embodiment may further include the magnetic shield 6 described in the first embodiment. As a result, the flat-type proximity sensor 100 according to the second embodiment also has the effect of the magnetic shield 6 described in the first embodiment.

The flat-type proximity sensor 100 according to the second embodiment may further include the cable 7 and the amplifier 8 described in the first embodiment. As a result, the flat-type proximity sensor 100 according to the second embodiment also has the effects of the cable 7 and the amplifier 8 described in the first embodiment.

The flat-type proximity sensor 100 according to the second embodiment may have the configuration described in the first embodiment in addition to the configuration described above.

### Modification of Second Embodiment

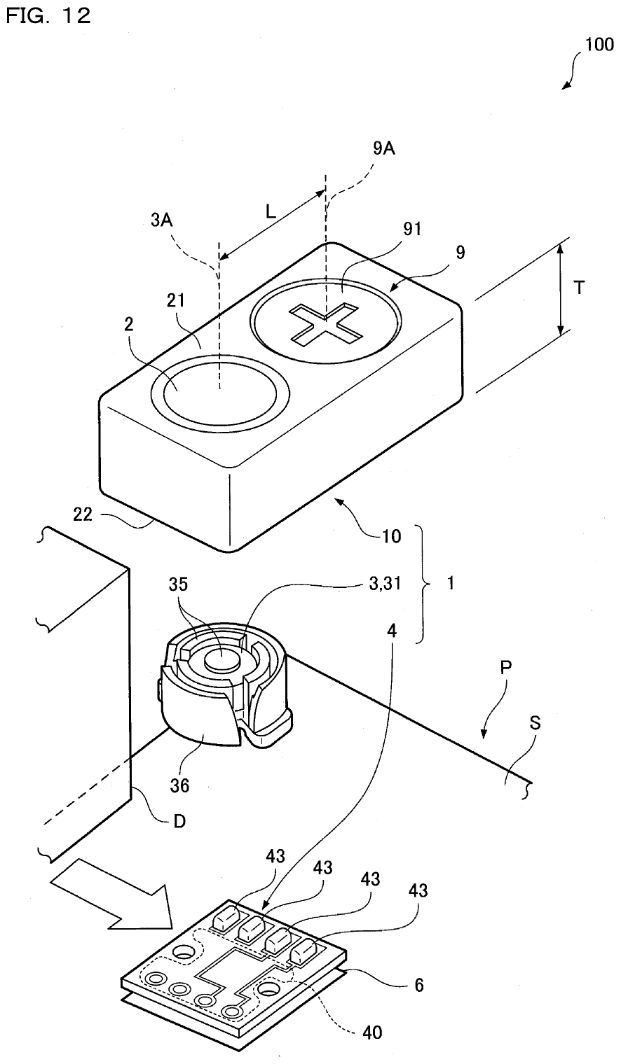

Hereinafter, a modification of the flat-type proximity sensor 100 according to the second embodiment will be described with reference to FIG. 12. FIG. 12 is an exploded perspective view illustrating an outline of a flat-type proximity sensor 100 according to the modification of the second embodiment.

In the flat-type proximity sensor 100 of the modification, as compared with the second embodiment, the size of the case member 10 is limited in different points, and the excitation current is limited to a pulse shape.

First, a premise of the modification will be described. The flat-type proximity sensor 100 in which the proximity sensor described in JP2018-152320A as the background art is the flat-type is used by being installed on the installation surface S of the plate-shaped member P or the like.

In the flat-type proximity sensor 100 in which the head body 1 is downsized, the magnetic field for detection is easily influenced. When the magnetic field is influenced, the detection distance becomes short.

Therefore, an object of the technical idea according to the flat-type proximity sensor 100 of the modification is to realize a long detection distance even though the flat-type proximity sensor is downsized.

As illustrated in FIG. 12, the flat-type proximity sensor 100 is a flat-type sensor that is installed on the installation surface S of the plate-shaped member P or the like and detects the detection object D in proximity to the plate-shaped member P or the like. The flat-type proximity sensor 100 includes the head body 1 installed on the installation surface S by the attachment screw 9.

The head body 1 includes a case member 10, a first coil 31 (an example of a coil 3), and a head board 4. The first surface 21 includes a detection surface 2 that detects the detection object D in proximity. The second surface 22 is a surface different from the first surface 21 and is installed on the installation surface S.

A thickness T of the case member 10 from the first surface 21 to an opposite surface is 7 mm or less, or a distance L from an axis 3A of the first coil 31 to an axis 9A of the attachment screw 9 is 9 mm or less.

The first coil 31 generates a magnetic field by applying the pulse-shaped excitation current. According to this configuration, the head board 4 includes a head circuit 40. A first detection current (an example of a detection current) flowing through the head circuit changes due to a change in a magnetic field.

When the case member 10 is thin such that the thickness T of the case member 10 is 7 mm or less, the coil 3 and the plate-shaped member P and the like become close to each other. In such a dimensional relationship, since the coil 3 and the plate-shaped member P are close to each other, in other words, the distance between a portion of the coil 3 on the opposite surface side and the installation surface S is equal to the detection distance of the detection object D by the coil 3, the magnetic field is easily influenced by the plate-shaped member P as much as the detection object D. Here, the excitation current has a pulse shape, and thus, the flat-type proximity sensor 100 can process the detection current by subtracting the influence of the plate-shaped member P or the like on the magnetic field. Accordingly, even in the configuration in which the thickness T of the case member 10 is 7 mm or less, a long detection distance can be realized.

When the distance L from the axis 3A of the coil 3 to the axis 9A of the attachment screw 9 (the center of the through-hole into which the attachment screw 9 is inserted) is 9 mm or less, there is a risk that a minimum interval between the coil 3 and the attachment screw 9 becomes equal to the detection distance, and the magnetic field is easily influenced by the attachment screw 9. More specifically, in a case where the attachment screw has a dimension conforming to the standard, a diameter of a flat dish portion is about 6 mm. In addition, the outer diameter of the coil 3 is preferably about 4 mm in order to secure the number of windings of the coil wire. With such a dimensional relationship, when the distance from the axis 3A of the coil 3 to the center of the through-hole into which the attachment screw 9 is inserted is 9 mm, the minimum interval between the coil 3 and the attachment screw 9 is 4 mm, and there is a risk that the minimum interval is equivalent to the detection distance of the detection object D. Here, the excitation current has a pulse shape, and thus, the flat-type proximity sensor 100 can process the detection current by subtracting the influence of the attachment screw 9 on the magnetic field. Accordingly, even in the configuration in which the distance from the axis 3A of the coil 3 to the center of the through-hole into which the attachment screw 9 is inserted is 9 mm or less, a long detection distance can be realized.

Incidentally, the above-described embodiments (the first embodiment, the first and second modifications of the first embodiment, the second embodiment, and the modification of the second embodiment) are examples in all respects and are not restrictive. The scope of the invention is indicated not by the above description but by the claims, and it is intended that meanings equivalent to the claims and all changes within the scope are included. Among the configurations described in the embodiments, configurations other than the configurations described as one aspect of the invention in “Means for Solving Problems” are any configurations, and can be appropriately deleted and changed.

(1) The configuration described as the coil 3 in the above-described embodiments may be only the first coil 31 or only the second coil 32, or may be both the first coil 31 and the second coil 32.

The invention provides the flat-type proximity sensor, and has industrial applicability.

What is claimed is:

1. A flat-type proximity sensor comprising:
a head body installed on an installation surface;
a cable; and
an amplifier,
wherein the head body includes
a case member having a first surface and a second surface, and
a coil and a head board accommodated in the case member,
the first surface includes a detection surface that detects a detection object in proximity,
the second surface is a surface different from the first surface, and is installed on the installation surface,
the coil generates a magnetic field by applying a pulse-shaped excitation current,
the head board includes a head circuit through which a detection current that changes due to a change in the magnetic field flows,
the cable guides the detection current from the head circuit to the amplifier, and
the amplifier includes a processing circuit that performs processing related to detection of the detection object based on the change in the detection current.

2. The flat-type proximity sensor according to claim 1,
wherein the coil includes
a first coil that generates the magnetic field by applying the pulse-shaped excitation current, and
a second coil different from the first coil,
a first detection current that changes due to the change in the magnetic field flows through the first coil,
a second detection current that changes due to the change in the magnetic field flows through the second coil,
the first detection current and the second detection current flow through the head circuit, and
the processing circuit performs the processing related to the detection of the detection object based on a change in the first detection current and a change in the second detection current.

3. The flat-type proximity sensor according to claim 1, further comprising:
an electric shield,
wherein the electric shield includes
a main plate along the detection surface, and
side plates erected on an outer peripheral edge of the main plate, and
a cut is formed in the main plate.

4. The flat-type proximity sensor according to claim 3, wherein the main plate and the side plates are along an inner surface of the case member.

5. The flat-type proximity sensor according to claim 3,
wherein the electric shield further includes a back plate facing the main plate, and
the main plate, the side plates, and the back plate surround the head board.

6. The flat-type proximity sensor according to claim 3,
wherein the case member is made of metal, and
the head body further includes an insulating member that insulates the case member and the electric shield from each other.

7. The flat-type proximity sensor according to claim 6, wherein the insulating member includes an insulating resin.

8. The flat-type proximity sensor according to claim 6, wherein the insulating member is an insulating material coated on an inner surface of the case member.

9. The flat-type proximity sensor according to claim 1, wherein the detection surface is made of metal.

10. The flat-type proximity sensor according to claim 1, further comprising:
a magnetic shield,
wherein the magnetic shield is disposed on an opposite surface side of the detection surface with respect to the coil.

11. The flat-type proximity sensor according to claim 1,
wherein the case member exposes an opposite surface to the first surface, and
the head body further includes a filling resin on the exposed opposite surface of the case member.

12. The flat-type proximity sensor according to claim 1,
wherein the head board includes
a board front surface facing a back surface of the first surface, and
a terminal provided on the board front surface,
the board front surface includes a non-shielding portion that is not shielded inside the case member, and
the terminal is positioned in the non-shielding portion.
